(19) United States
(12) Patent Application Publication
(10) Pub. No.: US 2026/0006828 A1
(43) Pub. Date: Jan. 1, 2026

(54) SEMICONDUCTOR DEVICE AND MANUFACTURING METHOD THEREOF

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Akihiro HANADA, Tokyo (JP); Takaya TAMARU, Tokyo (JP); Marina MOCHIZUKI, Tokyo (JP); Ryo ONODERA, Tokyo (JP)

(73) Assignee: Japan Display Inc., Tokyo (JP)

(21) Appl. No.: 19/322,823

(22) Filed: Sep. 9, 2025

Related U.S. Application Data
(63) Continuation of application No. PCT/JP2024/002595, filed on Jan. 29, 2024.

(30) Foreign Application Priority Data
Mar. 16, 2023 (JP) 2023-041930

(51) Int. Cl. H10D 30/67; H10D 30/01; H10D 62/60

(52) U.S. Cl. CPC H10D 30/6723; H10D 30/0314; H10D 30/6731; H10D 30/6755; H10D 62/60

(57) ABSTRACT

A semiconductor device includes an oxide insulating layer, an oxide semiconductor layer, a gate insulating layer, and a gate electrode. In a first region in which the oxide insulating layer, the oxide semiconductor layer, the gate insulating layer, and the gate electrode are stacked in this order, the gate electrode contains an impurity. In a second region in which the oxide insulating layer, the oxide semiconductor layer, and the gate insulating layer are stacked in this order, the oxide insulating layer, the oxide semiconductor layer, and the gate insulating layer contain the impurity. In a third region in which the oxide insulating layer and the gate insulating layer are stacked in this order, the oxide insulating layer and the gate insulating layer contain the impurity. In a stacked direction of the second region, a concentration profile of the impurity comprises a first peak and a second peak.

### CROSS-REFERENCE TO RELATED APPLICATIONS

This application is a Continuation of International Patent Application No. PCT/JP2024/002595, filed on Jan. 29, 2024, which claims the benefit of priority to Japanese Patent Application No. 2023-041930, filed on Mar. 16, 2023, the entire contents of which are incorporated herein by reference.

### FIELD

An embodiment of the present invention relates to a semiconductor device using an oxide semiconductor film for a channel and a method for manufacturing the semiconductor device.

### BACKGROUND

In recent years, instead of a silicon semiconductor film using amorphous silicon, low-temperature polysilicon, and single-crystal silicon, a semiconductor device in which an oxide semiconductor film is used for a channel has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device including an oxide semiconductor film can be fabricated with a simple structure and low-temperature process, similar to a semiconductor device including an amorphous silicon film. The semiconductor device including an oxide semiconductor film is known to have higher mobility than the semiconductor device including an amorphous silicon film.

### SUMMARY

A semiconductor device according to an embodiment of the present invention includes an oxide insulating layer, an oxide semiconductor layer over the oxide insulating layer, a gate insulating layer over the oxide semiconductor layer, and a gate electrode over the gate insulating layer. In a first region in which the oxide insulating layer, the oxide semiconductor layer, the gate insulating layer, and the gate electrode are stacked in this order, the gate electrode contains an impurity. In a second region in which the gate electrode is not included and the oxide insulating layer, the oxide semiconductor layer, and the gate insulating layer are stacked in this order, the oxide insulating layer, the oxide semiconductor layer, and the gate insulating layer contain the impurity. In a third region in which the gate electrode and the oxide semiconductor layer are not included and the oxide insulating layer and the gate insulating layer are stacked in this order, the oxide insulating layer and the gate insulating layer contain the impurity. In a stacked direction of the second region, a concentration profile of the impurity comprises a first peak and a second peak.

A semiconductor device according to an embodiment of the present invention includes an oxide insulating layer, an oxide semiconductor layer over the oxide insulating layer, a gate insulating layer over the oxide semiconductor layer, and a gate electrode over the gate insulating layer. In a first region in which the oxide insulating layer, the oxide semiconductor layer, the gate insulating layer, and the gate electrode are stacked in this order, the gate electrode contains an impurity. In a second region in which the gate electrode is not included and the oxide insulating layer, the oxide semiconductor layer, and the gate insulating layer are stacked in this order, the oxide semiconductor layer and the gate insulating layer contain the impurity. In a third region in which the gate electrode and the oxide semiconductor layer are not included and the oxide insulating layer and the gate insulating layer are stacked in this order, the oxide insulating layer and the gate insulating layer contain the impurity. In a stacked direction of the third region, a concentration profile of the impurity comprises a first peak and a second peak.

A method for manufacturing a semiconductor device according to an embodiment of the present invention includes the steps of forming an oxide insulating layer, forming a mask layer having a first pattern over the oxide insulating layer, implanting a first impurity into the oxide insulating layer using the mask layer as a mask, forming an oxide semiconductor layer having a second pattern over the oxide insulating layer, forming a gate insulating layer over the oxide insulating layer and the oxide semiconductor layer so as to cover the oxide semiconductor layer, forming a gate electrode having a third pattern over the gate insulating layer, and implanting a second impurity into the oxide semiconductor layer using the gate electrode as a mask.

A method for manufacturing a semiconductor device according to an embodiment of the present invention includes the steps of forming an oxide insulating layer, forming an oxide semiconductor layer having a first pattern over the oxide insulating layer, implanting a first impurity into the oxide insulating layer using a resist having the first pattern for forming the oxide semiconductor layer as a mask, forming a gate insulating layer over the oxide insulating layer and the oxide semiconductor layer so as to cover the oxide semiconductor layer, forming a gate electrode having a second pattern over the gate insulating layer, and implanting a second impurity into the oxide semiconductor layer using the gate electrode as a mask.

### BRIEF DESCRIPTION OF DRAWINGS

FIG. 1 is a cross-sectional view showing an outline of a semiconductor device according to an embodiment of the present invention.

FIG. 2 is a plan view showing an outline of a semiconductor device according to an embodiment of the present invention;

FIG. 3 is a schematic enlarged partial cross-sectional view showing a configuration of a semiconductor device according to an embodiment of the present invention.

FIG. 4A is a graph showing a concentration profile of an impurity in a first region in a semiconductor device according to an embodiment of the present invention.

FIG. 4B is a graph showing a concentration profile of an impurity in a second region in a semiconductor device according to an embodiment of the present invention.

FIG. 4C is a graph showing a concentration profile of an impurity in a third region in a semiconductor device according to an embodiment of the present invention.

FIG. 5A is a graph showing a concentration profile of an impurity in a first region in a semiconductor device according to an embodiment of the present invention.

FIG. 5B is a graph showing a concentration profile of an impurity in a second region in a semiconductor device according to an embodiment of the present invention.

FIG. 5C is a graph showing a concentration profile of an impurity in a third region in a semiconductor device according to an embodiment of the present invention.

FIG. 6 is a sequence diagram showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a method for manufacturing a semiconductor device according to an embodiment of the present invention.

FIG. 14 is a cross-sectional view showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a cross-sectional view showing a method for manufacturing a semiconductor device according to an embodiment of the present invention.

FIG. 19 is a schematic cross-sectional view illustrating hydrogen trapping regions in second and third regions in a semiconductor device according to an embodiment of the present invention.

FIG. 20 is a schematic cross-sectional view illustrating hydrogen trapping regions in second and third regions in a semiconductor device according to an embodiment of the present invention.

FIG. 21 is a schematic enlarged partial cross-sectional view showing a configuration of a semiconductor device according to an embodiment of the present invention.

FIG. 22A is a graph showing a concentration profile of an impurity in a first region in a semiconductor device according to an embodiment of the present invention.

FIG. 22B is a graph showing a concentration profile of an impurity in a second region in a semiconductor device according to an embodiment of the present invention.

FIG. 22C is a graph showing a concentration profile of an impurity in a third region in a semiconductor device according to an embodiment of the present invention.

FIG. 23A is a graph showing a concentration profile of an impurity in a first region in a semiconductor device according to an embodiment of the present invention.

FIG. 23B is a graph showing a concentration profile of an impurity in a second region in a semiconductor device according to an embodiment of the present invention.

FIG. 23C is a graph showing a concentration profile of an impurity in a third region in a semiconductor device according to an embodiment of the present invention.

FIG. 24 is a sequence diagram showing a method for manufacturing a semiconductor device according to an embodiment of the present invention.

FIG. 25 is a cross-sectional view showing a method for manufacturing a semiconductor device according to an embodiment of the present invention.

FIG. 26 is a cross-sectional view showing a method for manufacturing a semiconductor device according to an embodiment of the present invention.

### DESCRIPTION OF EMBODIMENTS

In an oxide semiconductor, carriers are generated when hydrogen bonds to oxygen deficiencies. In a semiconductor device, this mechanism can be used to form a source region and a drain region, which are low-resistance regions, by forming oxygen deficiencies in an oxide semiconductor layer and supplying hydrogen to the oxygen deficiencies. On the other hand, when hydrogen diffuses into a channel region of the oxide semiconductor layer, characteristics of the semiconductor device as a channel deteriorate. Specifically, the diffusion of hydrogen into the channel region CH changes the threshold voltage in the electrical characteristics of the semiconductor device, so that the variation in the threshold voltage increases and the manufacturing yield of the semiconductor device decreases. Therefore, using an oxide layer containing excessive oxygen capable of trapping hydrogen as an insulating layer in contact with the oxide semiconductor layer makes it possible to suppress hydrogen from entering the channel region.

However, since the oxide layer containing excessive oxygen functions as an electron-trap, the reliability of the semiconductor device containing such an oxide layer is significantly reduced. Therefore, there is a demand for a semiconductor device capable of suppressing a decrease in reliability, supplying hydrogen to the source region and the drain region of the oxide semiconductor layer, and suppressing hydrogen from entering the channel region of the oxide semiconductor layer.

In view of the above problem, an embodiment of the present invention can provide a semiconductor device including a hydrogen trapping region that prevents hydrogen from entering a channel region.

Each embodiment of the present invention is described below with reference to the drawings. The following disclosure is merely an example. A configuration that can be easily conceived by a person skilled in the art by appropriately changing the configuration of the embodiment while maintaining the gist of the invention is naturally included in the scope of the present invention. For the sake of clarity of description, the drawings may be schematically represented with respect to widths, thicknesses, shapes, and the like of the respective portions in comparison with actual embodiments. However, the shape shown is merely an example and does not limit the interpretation of the present invention. In this specification and each of the drawings, the same symbols are assigned to the same components as those described previously with reference to the preceding drawings, and a detailed description thereof may be omitted as appropriate.

In each embodiment of the present invention, a direction from a substrate to an oxide semiconductor layer is referred to as “on” or “over.” Reversely, a direction from the oxide semiconductor layer to the substrate is referred to as “under” or “below.” In this way, for convenience of explanation, although the phrase “over (on)” or “below (under)” is used for explanation, for example, a vertical relationship between the substrate and the oxide semiconductor layer may be arranged in a different direction from that shown in the drawing. In the following description, for example, the expression “the oxide semiconductor layer on the substrate” merely describes the vertical relationship between the substrate and the oxide semiconductor layer as described above, and other members may be arranged between the substrate and the oxide semiconductor layer. “Over” or “below” means a stacking order in a structure in which multiple layers are stacked, and when it is expressed as a pixel electrode over a transistor, it may be a positional relationship where the transistor and the pixel electrode do not overlap each other in a plan view. On the other hand, when it is expressed as a pixel electrode vertically over a transistor, it means a positional relationship where the transistor and the pixel electrode overlap each other in a plan view.

In the present specification, the terms “film” and “layer” can optionally be interchanged each other.

In the present specification, “display device” refers to a structure configured to display an image using electro-optic layers. For example, the term display device may refer to a display panel including the electro-optic layer, or it may refer to a structure in which other optical members (e.g., polarizing member, backlight, touch panel, etc.) are attached to a display cell. The “electro-optic layer” can include a liquid crystal layer, an electroluminescence (EL) layer, an electrochromic (EC) layer, and an electrophoretic layer, as long as there is no technical contradiction. Therefore, although the embodiments described later are described by exemplifying the liquid crystal display device including a liquid crystal layer and an organic EL display device including an organic EL layer as the display device, the structure in the present embodiment can be applied to a display device including the other electro-optic layers described above.

In the present specification, the expressions “α includes A, B, or C,” “α includes any of A, B, and C,” and “α includes one selected from a group consisting of A, B, and C” do not exclude the case where a includes multiple combinations of A to C unless otherwise specified. Furthermore, these expressions do not exclude the case where α includes other elements.

In addition, the following embodiments can be combined with each other as long as there is no technical contradiction.

### First Embodiment

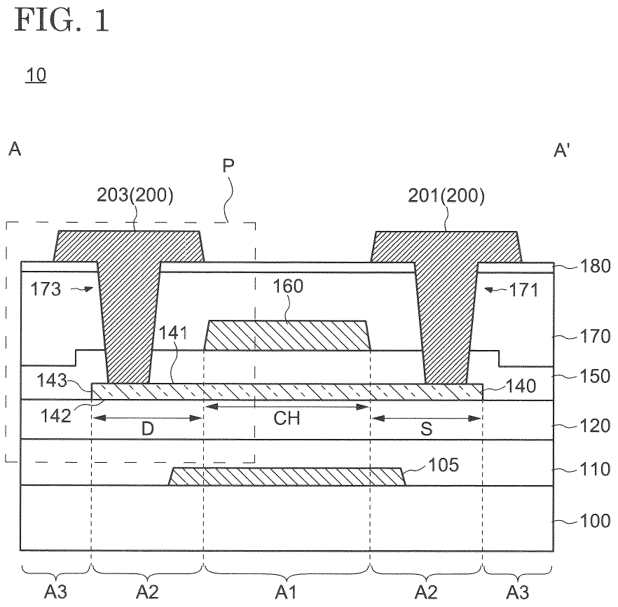

A semiconductor device 10 according to an embodiment of the present invention is described with reference to FIGS. 1 to 20. For example, the semiconductor device 10 of the embodiment described below may be used in an integrated circuit (IC) such as a micro-processing unit (MPU) or a memory circuit in addition to a transistor used in a display device.

### 1. Configuration of Semiconductor Device 10

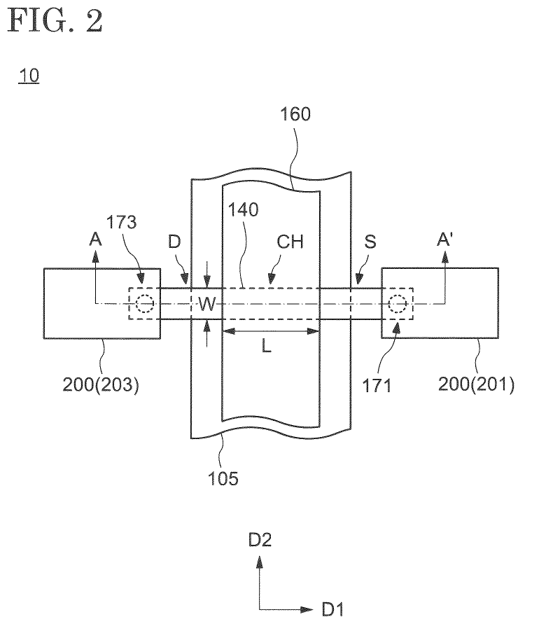

A configuration of a semiconductor device 10 according to an embodiment of the present invention is described with reference to FIGS. 1 and 2. FIG. 1 is a cross-sectional view showing an outline of the semiconductor device 10 according to an embodiment of the present invention. FIG. 2 is a plan view showing an outline of the semiconductor device 10 according to an embodiment of the present invention. Specifically, FIG. 1 is a cross-sectional view taken along a line A-A′ in FIG. 2.

As shown in FIG. 1, the semiconductor device 10 is arranged above a substrate 100. The semiconductor device 10 includes a light shielding layer 105, a nitride insulating layer 110, an oxide insulating layer 120, a metal oxide layer 130, an oxide semiconductor layer 140, a gate insulating layer 150, a gate electrode 160, insulating layers 170 and 180, a source electrode 201, and a drain electrode 203. If the source electrode 201 and the drain electrode 203 are not specifically distinguished from each other, they may be referred to as a source-drain electrode 200.

The light shielding layer 105 is arranged on the substrate 100. The nitride insulating layer 110 and the oxide insulating layer 120 are arranged on the substrate 100 and the light shielding layer 105. The nitride insulating layer 110 covers an upper surface and an end portion of the light shielding layer 105. The oxide semiconductor layer 140 is arranged on the oxide insulating layer 120. The oxide semiconductor layer 140 is patterned. A part of the oxide insulating layer 120 extends outside the pattern of the oxide semiconductor layer 140 beyond end portions of the oxide semiconductor layer 140.

In the present embodiment, although a configuration in which the oxide insulating layer 120 and the oxide semiconductor layer 140 are in contact with each other is exemplified, the configuration is not limited to this configuration. For example, a metal oxide layer may be arranged between the oxide insulating layer 120 and the oxide semiconductor layer 140. For example, a metal oxide containing aluminum as the main component may be used as the metal oxide layer. Specifically, aluminum oxide may be used as the metal oxide layer.

The gate insulating layer 150 is arranged on the oxide semiconductor layer 140 so as to cover an upper surface 141 and a side surface 143 of the oxide semiconductor layer 140. That is, the upper surface 141 and the side surface 143 of the oxide semiconductor layer 140 are in contact with the gate insulating layer 150, and the lower surface 142 of the oxide semiconductor layer 140 is in contact with the oxide insulating layer 120. The gate electrode 160 is provided on the gate insulating layer 150 so as to face the oxide semiconductor layer 140.

The insulating layer 170 is arranged on the gate insulating layer 150 and the gate electrode 160. The insulating layer 170 covers the gate electrode 160. The insulating layer 180 is arranged on the insulating layer 170. Openings 171 and 173 that reach the oxide semiconductor layer 140 are arranged in the insulating layers 170 and 180. The source electrode 201 is arranged inside the opening 171. The source electrode 201 is in contact with the oxide semiconductor layer 140 at the bottom of the opening 171. The drain electrode 203 is arranged inside the opening 173. The drain electrode 203 is in contact with the oxide semiconductor layer 140 at the bottom of the opening 173.

The light shielding layer 105 has a function that shields light incident to the oxide semiconductor layer 140 from a side of the substrate 100. The nitride insulating layer 110 functions as a barrier film that shields impurities that diffuse from the substrate 100 toward the oxide semiconductor layer 140. The light shielding layer 105 may have a function as a bottom gate of the semiconductor device 10. In this case, the nitride insulating layer 110 and the oxide insulating layer 120 have a function as gate insulating layers for the bottom gate.

The operation of the semiconductor device 10 is controlled mainly by a voltage supplied to the gate electrode 160. In the case where the light shielding layer 105 has a function as the bottom gate, an auxiliary voltage is supplied to the light shielding layer 105. However, a voltage similar to the voltage supplied to the gate electrode 160 may be supplied to the light shielding layer 105. On the other hand, in the case where the light shielding layer 105 is simply used as a light shielding film, a particular voltage is not supplied to the light shielding layer 105, and the potential of the light shielding layer 105 may be floating. Alternatively, the light shielding layer 105 may be an insulator.

The semiconductor device 10 is divided into a first region A1, a second region A2, and a third region A3 based on the patterns of the gate electrode 160 and the oxide semiconductor layer 140. The first region A1 is a region that overlaps the gate electrode 160 in a planar view. In the first region A1, the oxide insulating layer 120, the oxide semiconductor layer 140, the gate insulating layer 150, and the gate electrode 160 are stacked in this order. The second region A2 is a region that does not overlap the gate electrode 160 and overlaps the oxide semiconductor layer 140 in a planar view. In the second region A2, the oxide insulating layer 120, the oxide semiconductor layer 140, and the gate insulating layer 150 are stacked in this order. The third region A3 is a region that does not overlap both the gate electrode 160 and the oxide semiconductor layer 140 in a planar view. In the third region A3, the oxide insulating layer 120 and the gate insulating layer 150 are stacked in this order.

The thickness of the gate insulating layer 150 is, for example, greater than or equal to 100 nm. The thickness of the gate insulating layer 150 may be greater than or equal to 250, or greater than or equal to 300 nm.

The oxide semiconductor layer 140 is divided into a source region S, a drain region D, and a channel region CH based on the pattern of the gate electrode 160. The source region S and the drain region D are regions corresponding to the second region A2. The channel region CH is a region corresponding to the first region A1. In a plan view, an end portion in the channel region CH is consistent with an end portion of the gate electrode 160. The oxide semiconductor layer 140 in the channel region CH has semiconductor properties. Each of the oxide semiconductor layer 140 in the source region S and the drain region D has conductive properties. That is, carrier concentrations of the oxide semiconductor layer 140 in the source region S and the drain region D are higher than a carrier concentration of the oxide semiconductor layer 140 in the channel region CH. The source electrode 201 and the drain electrode 203 are in contact with the source region S and the drain region D, respectively, and are electrically connected to the oxide semiconductor layer 140. The oxide semiconductor layer 140 may be a single-layer structure or a stacked structure.

In the present embodiment, although a top-gate transistor in which the gate electrode 160 is arranged above the oxide semiconductor layer 140 is exemplified as the semiconductor device 10, the semiconductor device 10 is not limited to this configuration. For example, as described above, the semiconductor device 10 may be a dual-gate transistor in which the light shielding layer 105 functions as a gate in addition to the gate electrode 160. Alternatively, the semiconductor device 10 may be a bottom-gate transistor in which the light shielding layer 105 mainly functions as a gate. The above configurations are merely embodiments, and the present invention is not limited to the above configurations.

In a direction D1 shown in FIG. 2, a width of the light shielding layer 105 is greater than a width of the gate electrode 160. The direction D1 is a direction connecting the source electrode 201 and the drain electrode 203, and is a direction indicating a channel length L of the semiconductor device 10. Specifically, a length in the direction D1 in the region (the channel region CH) where the oxide semiconductor layer 140 overlaps the gate electrode 160 is the channel length L, and a width in a direction D2 in the channel region CH is a channel width W. The light shielding layer 105 and the gate electrode 160 extend in the direction D2.

In FIG. 2, although a configuration in which the source-drain electrode 200 does not overlap the light shielding layer 105 and the gate electrode 160 in a plan view is exemplified, the configuration is not limited to this configuration. For example, in a plan view, the source-drain electrode 200 may overlap at least one of the light shielding layer 105 and the gate electrode 160. The above configuration is merely an embodiment, and the present invention is not limited to the above configuration.

### 2. Material of Each Member of Semiconductor Device 10

A rigid substrate having translucency, such as a glass substrate, a quartz substrate, a sapphire substrate, or the like, is used as the substrate 100. In the case where the substrate 100 needs to have flexibility, a substrate containing a resin such as a polyimide substrate, an acryl substrate, a siloxane substrate, or a fluororesin substrate is used as the substrate 100. In the case where the substrate containing a resin is used as the substrate 100, impurities may be introduced into the resin in order to improve the heat resistance of the substrate 100. In particular, in the case where the semiconductor device 10 is a top-emission display, since the substrate 100 does not need to be transparent, impurities that deteriorate the translucency of the substrate 100 may be used. In the case where the semiconductor device 10 is used for an integrated circuit that is not a display device, a non-transparent substrate such as a semiconductor substrate such as a silicon substrate, a silicon carbide substrate, a compound semiconductor substrate, or a conductive substrate such as a stainless substrate is used as the substrate 100.

Common metal materials are used for the light shielding layer 105, the gate electrode 160, and the source-drain electrode 200. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), or alloys or compounds thereof are used for these members. The above-described materials may be used in a single layer or a stacked layer for the light shielding layer 105, the gate electrode 160, and the source-drain electrode 200. A material other than the above-described metal materials may be used for the light shielding layer 105 if conductivity is not required. For example, a black matrix such as a black resin may be used as the light shielding layer 105. The light shielding layer 105 may be a single-layer structure or a stacked structure. For example, the light shielding layer 105 may be a stacked structure of a red color filter, a green color filter, and a blue color filter.

Common insulating materials are used for the nitride insulating layer 110, the oxide insulating layer 120, and the insulating layers 170 and 180. For example, inorganic insulating materials such as silicon oxide (SiOₓ), silicon oxynitride (SiOₓN_{y}), aluminum oxide (AlOₓ), or aluminum oxynitride (AlOₓN_{y}) is used for the oxide insulating layer 120 and the insulating layer 180. Inorganic insulating materials such as silicon nitride (SiNₓ), silicon nitride oxide (SiNₓO_{y}), aluminum nitride (AlNₓ), or aluminum nitride oxide (AlNₓO_{y}) is used for the nitride insulating layer 110 and the insulating layer 170. However, the inorganic insulating material such as silicon oxide (SiOₓ), silicon oxynitride (SiOₓN_{y}), aluminum oxide (AlOₓ), or aluminum oxynitride (AlOₓN_{y}) may be used for the insulating layer 170. The inorganic insulating material such as silicon nitride (SiNₓ), silicon nitride oxide (SiNₓO_{y}), aluminum nitride (AlNₓ), or aluminum nitride oxide (AlNₓO_{y}) may be used for the insulating layer 180.

The inorganic insulating material containing oxygen is used for the gate insulating layer 150. For example, an inorganic insulating material such as silicon oxide (SiOₓ), silicon oxynitride (SiOₓN_{y}), aluminum oxide (AlOₓ), or aluminum oxynitride (AlOₓN_{y}) is used for the gate insulating layer 150.

An insulating material having a function of releasing oxygen by a heat treatment is used for the oxide insulating layer 120. That is, an oxide insulating material containing excess oxygen is used for the oxide insulating layer 120. For example, the temperature of a heat treatment at which the oxide insulating layer 120 releases oxygen is less than or equal to 600° C., less than or equal to 500° C., less than or equal to 450° C., or less than or equal to 400° C. That is, for example, the oxide insulating layer 120 releases oxygen at a heat treatment temperature performed in a manufacturing process of the semiconductor device 10 when a glass substrate is used as the substrate 100. Similar to the oxide insulating layer 120, an insulating layer having a function of releasing oxygen by a heat treatment may be used for at least one of the insulating layers 170 and 180.

An insulating material with few defects is used for the gate insulating layer 150. For example, when a composition ratio of oxygen in the gate insulating layer 150 is compared with a composition ratio of oxygen in an insulating layer (hereinafter referred to as “other insulating layer”) having a composition similar to that of the gate insulating layer 150, the composition ratio of oxygen in the gate insulating layer 150 is closer to the stoichiometric ratio with respect to the insulating layer than the composition ratio of oxygen in that other insulating layer. Specifically, in the case where silicon oxide (SiOₓ) is used for each of the gate insulating layer 150 and the insulating layer 180, the composition ratio of oxygen in the silicon oxide used for the gate insulating layer 150 is close to the stoichiometric ratio of silicon oxide as compared with the composition ratio of oxygen in the silicon oxide used for the insulating layer 180. For example, an insulating material in which no defects are observed when evaluated by an electron-spin resonance (ESR) method may be used for the gate insulating layer 150.

SiOₓN_{y} and AlOₓN_{y} described above are a silicon compound and an aluminum compound containing nitrogen (N) in a ratio (x>y) smaller than that of oxygen (O). SiNₓO_{y} and AlNₓO_{y} are a silicon compound and an aluminum compound containing oxygen in a ratio (x>y) smaller than that of nitrogen.

A metal oxide having semiconductor properties can be used for the oxide semiconductor layer 140.

Although a detailed method of manufacturing the oxide semiconductor layer 140 is described later, the oxide semiconductor layer 140 can be formed using a sputtering method. A composition of the oxide semiconductor layer 140 formed by the sputtering method depends on a composition of a sputtering target. In this case, the composition of the metal element of the oxide semiconductor layer 140 can be specified based on the composition of the metal element of the sputtering target.

In the case where the oxide semiconductor layer 140 has a polycrystalline structure, a composition of the oxide semiconductor layer may be specified using an X-ray diffraction (X-ray Diffraction: XRD) method. Specifically, a composition of the metal element of the oxide semiconductor layer can be specified based on the crystalline structure and the lattice constant of the oxide semiconductor layer obtained by the XRD method. Furthermore, the composition of the metal element of the oxide semiconductor layer 140 can also be identified using fluorescent X-ray analysis, Electron Probe Micro Analyzer (EPMA) analysis, or the like. However, the oxygen contained in the oxide semiconductor layer 140 may not be specified by these methods because the oxygen varies depending on the sputtering process conditions.

As described above, the oxide semiconductor layer 140 may have an amorphous structure or a polycrystalline structure.

As described above, in the case where a metal oxide layer is arranged between the oxide insulating layer 120 and the oxide semiconductor layer 140, a metal oxide containing aluminum as the main component is used for the metal oxide layer. For example, an inorganic insulating material such as aluminum oxide (AlOₓ), aluminum oxynitride (AlOₓN_{y}), or aluminum nitride oxide (AlNₓO_{y}) is used for the metal oxide layer. The “metal oxide layer containing aluminum as the main component” means that the ratio of aluminum contained in the metal oxide layer is greater than or equal to 1% of the total amount of the metal oxide layer. The ratio of aluminum contained in the metal oxide layer may be greater than or equal to 5% and less than or equal to 70%, greater than or equal to 10% and less than or equal to 60%, or greater than or equal to 30% and less than or equal to 50% of the total amount of the metal oxide layer. The ratio may be a mass ratio or a weight ratio.

### 3. Configuration of Hydrogen Trapping Region

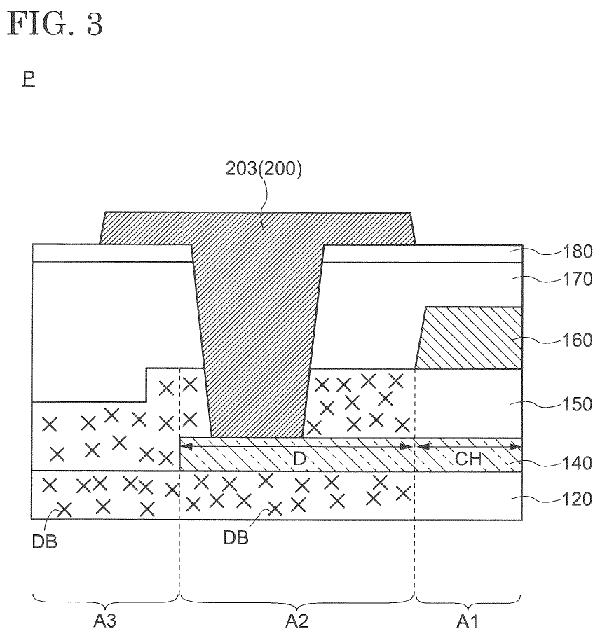

A hydrogen trapping region is formed in the oxide insulating layer 120 and the gate insulating layer 150. A configuration of the hydrogen trapping region formed in the oxide insulating layer 120 and the gate insulating layer 150 is described with reference to FIGS. 3, 4A to 4C, and 5A to 5C.

FIG. 3 is a schematic partially enlarged cross-sectional view showing a configuration of the semiconductor device 10 according to an embodiment of the present invention. Specifically, FIG. 3 is an enlarged cross-sectional view of a region P in FIG. 1. Although the region P shown in FIG. 3 is a region in the vicinity of the drain region D, the vicinity of the source region S also has the same configuration as the region P.

Although details are described later, the source region S and the drain region D of the oxide semiconductor layer 140 are formed by ion implantation of an impurity using the gate electrode 160 as a mask. Boron (B), phosphorus (P), argon (Ar), or nitrogen (N) can be used as the impurity. The ion implantation of the impurity generates oxygen deficiencies in the source region S and the drain region D. When hydrogen bonds with the generated oxygen deficiencies, the resistance of the source region S and the drain region D is reduced. Silicon nitride contains more hydrogen than silicon oxide. Therefore, when silicon nitride is used for the insulating layer 170, hydrogen is diffused from the insulating layer 170, thereby reducing the resistance of the source region S and the drain region D.

The impurity ions are implanted into the oxide semiconductor layer 140 through the gate insulating layer 150 using the gate electrode 160 as a mask. Therefore, the impurity is also introduced into the gate insulating layer 150 in the second region A2 and the third region A3, thereby forming dangling bond defects DB in the gate insulating layer 150. Further, in the second region A2 and the third region A3, the impurity may pass through the oxide semiconductor layer 140 and the gate insulating layer 150 and be introduced into the oxide insulating layer 120. In addition, the impurity ions are implanted into the oxide insulating layer 120 separately from the above-described ion implantation of the impurity in order to form dangling bond defects DB in the oxide insulating layer 120 in the second region A2 and the third region A3 in the present embodiment.

As a result, as shown in FIG. 3, dangling bond defects DB are formed in the oxide insulating layer 120 and the gate insulating layer 150 in the second region A2 and the third region A3. When silicon oxide is used for each of the oxide insulating layer 120 and the gate insulating layer 150, silicon dangling bond defects DB are formed in the oxide insulating layer 120 and the gate insulating layer 150.

The dangling bond defects DB formed in the oxide insulating layer 120 and the gate insulating layer 150 trap hydrogen. That is, a hydrogen trapping region is formed in the oxide insulating layer 120 and the gate insulating layer 150 in the second region A2 and the third region A3. Therefore, since hydrogen diffused from the insulating layer 170 during the formation of the insulating layer 170 is trapped in the hydrogen trapping regions of the oxide insulating layer 120 and the gate insulating layer 150 in the second region A2 and the third region A3, hydrogen is prevented from entering the channel region CH. In addition, since hydrogen is trapped in the hydrogen trapping region, the hydrogen concentration of the gate insulating layer 150 in the second region A2 and the third region A3 is greater than the hydrogen concentration of the gate insulating layer 150 in the first region A1 after the insulating layer 170 is formed. Similarly, the hydrogen concentration of the oxide insulating layer 120 in the second region A2 and the third region A3 is greater than the hydrogen concentration of the oxide insulating layer 120 in the first region A1.

As described above, since the dangling bond defects DB in the hydrogen trapping region are formed by the ion implantation, the oxide insulating layer 120 and the gate insulating layer 150 contain an impurity introduced by the ion implantation. The distribution of the amount of dangling bond defects DB formed in the oxide insulating layer 120 and the gate insulating layer 150 corresponds to a concentration profile (sometimes referred to as a concentration gradient or concentration distribution) of the impurity contained therein. In other words, the position and amount of the dangling bond defects DB can be controlled by adjusting the concentration profile of the impurity introduced by ion implantation.

In order to prevent abnormalities in the electrical characteristics of the semiconductor device 10 from occurring due to hydrogen entering the channel region CH, it is effective to form dangling bond defects DB in the oxide insulating layer 120 in the second region A2 and the third region A3. Therefore, in the present embodiment, impurity ions are implanted into the oxide insulating layer 120 without passing through the gate insulating layer 150. This allows hydrogen trapping regions to be formed in the oxide insulating layer 120 in the second region A2 and the third region A3, regardless of the thickness of the gate insulating layer 150. Further, when the thickness of the gate insulating layer 150 increases, the high-voltage resistance of the gate insulating layer 150 can be improved. For example, the thickness of the gate insulating layer 150 is greater than or equal to 200 nm.

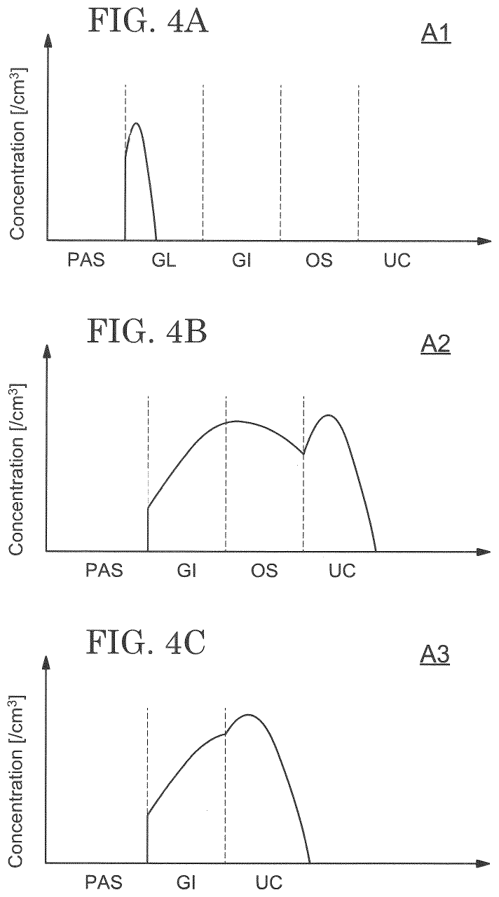

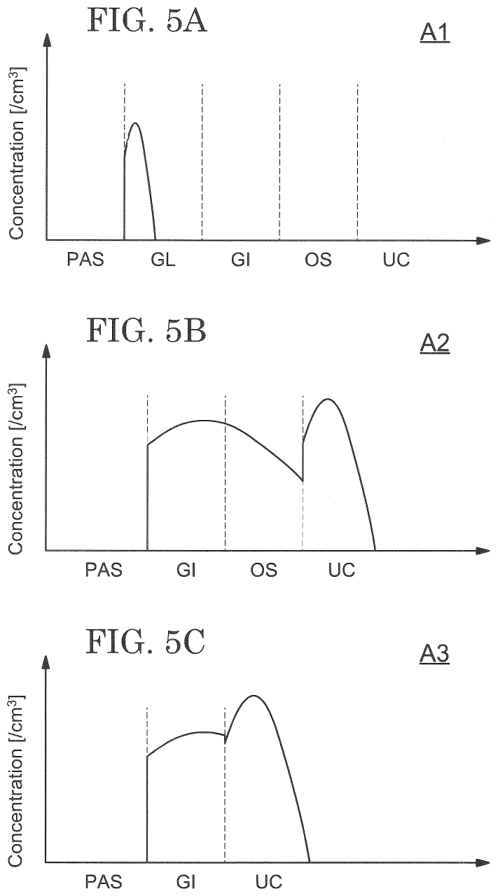

Each of FIGS. 4A to 4C and 5A to 5C is a graph showing concentration profiles of the impurity in the first region A1 to the third region A3 in a semiconductor device according to an embodiment of the present invention. Specifically, each of FIGS. 4A and 5A shows a concentration profile of the impurity in the first region A1, each of FIGS. 4B and 5B shows a concentration profile of the impurity in the second region A2, and each of FIGS. 4C and 5C shows a concentration profile of the impurity in the third region A3. In each of the graphs of FIGS. 4A to 4C and 5A to 5C, the vertical axis indicates the concentration of the impurity per unit volume (Concentration [/cm³]), and the horizontal axis indicates the name of the layer in the stacking direction (Film thickness direction). On the horizontal axis, “UC” corresponds to the oxide insulating layer 120 and the nitride insulating layer 110. “OS” corresponds to the oxide semiconductor layer 140. “GI” corresponds to the gate insulating layer 150. “GL” corresponds to the gate electrode 160. “PAS” corresponds to the insulating layer 170.

As shown in FIGS. 4A and 5A, the concentration profile of the impurity has peaks in the gate electrode 160 (GL) in the first region A1. That is, the first region A1 includes two peaks. Metal materials have a high blocking property for the impurity introduced by ion implantation. When a metal material is used for the gate electrode 160, the impurity is blocked by the gate electrode 160 and does not reach the gate insulating layer 150 (GI). Therefore, dangling bond defects DB due to the introduction of the impurity are not formed in the gate insulating layer 150 in the first region A1. However, the impurity may reach the gate insulating layer 150 as long as it does not affect the electrical characteristics of the semiconductor device 10.

As shown in FIG. 4B, the concentration profile of the impurity has peaks in the oxide insulating layer 120 (UC) and the oxide semiconductor layer 140 (OS) in the second region A2. That is, the second region A2 includes two peaks. In the stacking direction in the second region A2, the concentration of the impurity at the peak position of the oxide insulating layer 120 and the concentration of the impurity at the peak position of the oxide semiconductor layer 140 are greater than the concentration of the impurity in the gate insulating layer 150. The purpose of introducing the impurity into the second region A2 is to form the source region S and the drain region D. Therefore, although it is preferable to set the ion implantation conditions so as to obtain the above-described concentration profile, the concentration profile of the impurity is not limited thereto. The concentration profile of the impurity in the second region A2 may have peaks in the oxide insulating layer 120 (UC) and the gate insulating layer 150 (GI) (see FIG. 5B). In this case, in the stacking direction in the second region A2, the concentration of the impurity at the peak position of the oxide insulating layer 120 and the concentration of the impurity at the peak position of the gate insulating layer 150 may be greater than the concentration of the impurity in the oxide semiconductor layer 140.

As shown in FIG. 4C, the concentration profile of the impurity has a peak in the oxide insulating layer 120 (UC) in the third region A3. That is, the third region A3 includes one peak. In the stacking direction in the third region A3, the concentration of the impurity at the peak position of the oxide insulating layer 120 may be greater than the concentration of the impurity contained in the gate insulating layer 150. The concentration profile of the impurity of the gate insulating layer 150 in the third region A3 is substantially the same as the concentration profile of the impurity of the gate insulating layer 150 in the second region A2. Therefore, the concentration profile of the impurity in the third region A3 shown in FIG. 5C may have peaks in the oxide insulating layer 120 (UC) and the gate insulating layer 150 (GI). In this case, the third region A3 includes two peaks.

Although details are described later, at least two ion implantations of an impurity are performed in the present embodiment. In the first ion implantation of the impurity, the impurity ions are introduced into the oxide insulating layer 120 in the second region A2 and the third region A3. On the other hand, in the second ion implantation of the impurity, the impurity ions are introduced into the oxide insulating layer 120 in the second region A2 and the third region A3 through the gate insulating layer 150. Therefore, in the oxide insulating layer 120 in the first region A1, the second region A2, and the third region A3, the concentrations of the impurity may increase in the order of the first region A1, the second region A2, and the third region A3.

In the present embodiment, the concentration of the impurity contained at a predetermined position in the oxide insulating layer 120 in the stacking direction in the third region A3 is greater than or equal to 1×10¹⁶/cm³, greater than or equal to 1×10¹⁷/cm³, or greater than or equal to 1×10¹⁸/cm³. The predetermined position may be the peak position of the concentration profile, or may be a position corresponding to the interface between the oxide insulating layer 120 and the gate insulating layer 150. Alternatively, the predetermined position may be a position shifted by a predetermined depth toward the oxide insulating layer 120 from the position corresponding to the interface.

With reference to FIG. 2, the channel region CH corresponds to the first region A1, the source region S and the drain region D correspond to the second region A2, and the regions other than the channel region CH, the source region S, and the drain region D correspond to the third region A3. That is, the channel region CH is sandwiched by the second regions A2, and is surrounded by the third regions A3. Therefore, hydrogen diffused from the insulating layer 170 during the formation of the insulating layer 170 is trapped by hydrogen trapping regions formed in the oxide insulating layer 120 and the gate insulating layer 150 in the second region A2 and the third region A3 located around the channel region CH. As a result, it is possible to suppress the entry of the hydrogen into the channel region CH.

### 4. Method for Manufacturing Semiconductor Device 10

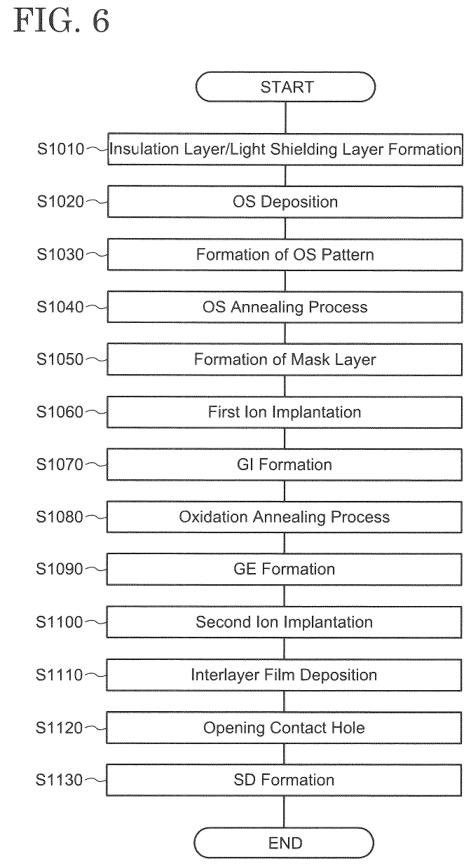

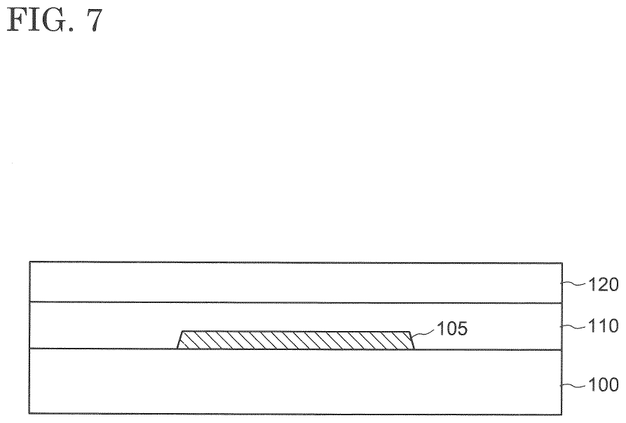

A method for manufacturing the semiconductor device 10 according to an embodiment of the present invention is described with reference to FIGS. 6 to 15. FIG. 6 is a sequence diagram showing a method for manufacturing the semiconductor device 10 according to an embodiment of the present invention. FIGS. 7 to 15 are cross-sectional views showing a method for manufacturing the semiconductor device 10 according to an embodiment of the present invention.

As shown in FIGS. 6 and 7, the light shielding layer 105 is formed on the substrate 100 as the bottom-gate, and the nitride insulating layer 110 and the oxide insulating layer 120 are formed on the light shielding layer 105 (“Insulation Layer/Light Shielding Layer Formation” in step S1010 of FIG. 6). For example, silicon nitride is formed for the nitride insulating layer 110. For example, silicon oxide is formed for the oxide insulating layer 120. The nitride insulating layer 110 and the oxide insulating layer 120 are deposited by a CVD (Chemical Vapor Deposition) method. For example, a thickness of the nitride insulating layer 110 is greater than or equal to 50 nm and less than or equal to 500 nm, or greater than or equal to 150 nm and less than or equal to 300 nm. For example, a thickness of the oxide insulating layer 120 is greater than or equal to 50 nm and less than or equal to 500 nm, or greater than or equal to 150 nm and less than or equal to 300 nm.

When silicon nitride is used for the nitride insulating layer 110, the nitride insulating layer 110 can block impurities diffusing from the substrate 100 toward the oxide semiconductor layer 140. For example, the silicon oxide used for the oxide insulating layer 120 is silicon oxide having a physical property of releasing oxygen by a heat treatment.

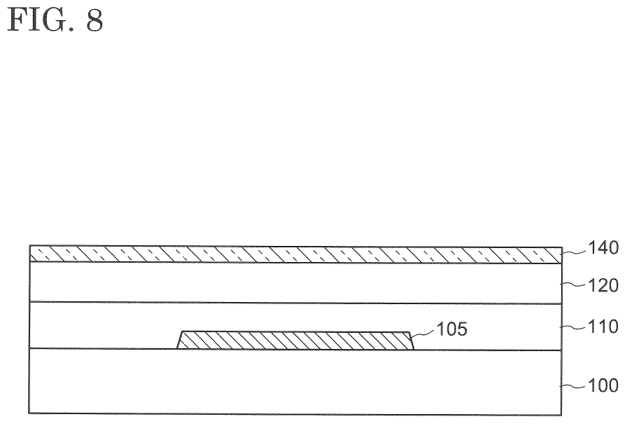

As shown in FIGS. 6 and 8, the oxide semiconductor layer 140 is formed on the oxide insulating layer 120 (“OS Deposition” in step S1020 in FIG. 6). The oxide semiconductor layer 140 is deposited by a sputtering method or an atomic layer deposition (ALD) method.

When a metal layer oxide layer containing aluminum as a main component is arranged between the oxide insulating layer 120 and the oxide semiconductor layer 140, the metal oxide layer is also deposited by a sputtering method or an atomic layer deposition method in the same manner as described above.

For example, a thickness of the oxide semiconductor layer 140 is greater than or equal to 10 nm and less than or equal to 100 nm, greater than or equal to 15 nm and less than or equal to 70 nm, or greater than or equal to 20 nm and less than or equal to 40 nm. In the present embodiment, the thickness of the oxide semiconductor layer 140 is 30 nm, for example. The oxide semiconductor layer 140 is amorphous before performing a heat treatment (OS annealing process) described later.

For example, when the oxide semiconductor layer 140 is deposited by a sputtering method, the oxide semiconductor layer 140 is deposited while controlling the temperature of the object on which the film is to be deposited (the substrate 100 and the structure formed thereon).

When the deposition is performed on the object to be deposited by the sputtering method, ions generated in the plasma and atoms recoiled by a sputtering target collide with the object to be deposited. Therefore, the temperature of the object to be deposited rises with the deposition process. For example, in order to control the temperature of the object to be deposited as described above, deposition may be performed while cooling the object to be deposited. For example, the object to be deposited may be cooled from a surface opposite to a deposition surface so that the temperature of the deposition surface of the object to be deposited (hereinafter, referred to as “deposition temperature”) is less than or equal to 100° C., less than or equal to 70° C., less than or equal to 50° C., or less than or equal to 30° C. An oxygen partial pressure in the deposition conditions of the oxide semiconductor layer 140 is greater than or equal to 2% and less than or equal to 20%, greater than or equal to 3% and less than or equal to 15%, or greater than or equal to 3% and less than or equal to 10%.

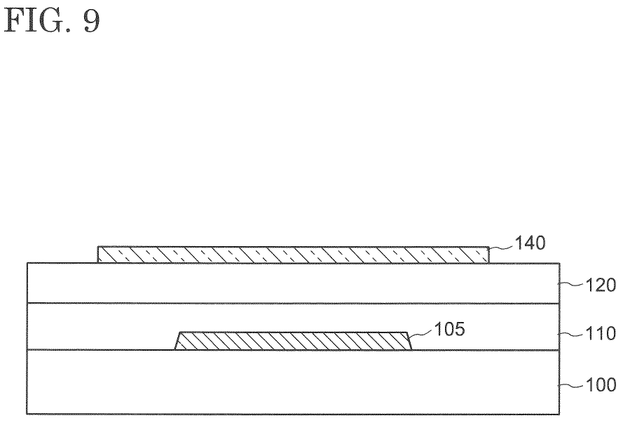

As shown in FIG. 6 and FIG. 9, a pattern of the oxide semiconductor layer 140 is formed (“Formation of OS Pattern” in step S1030 of FIG. 6). Although not shown in the figures, a resist mask is formed on the oxide semiconductor layer 140, and the oxide semiconductor layer 140 is etched using the resist mask. Wet etching may be used, or dry etching may be used for etching of the oxide semiconductor layer 140. Wet etching may be performed using an acidic etchant. For example, oxalic acid, PAN, sulfuric acid, hydrogen peroxide or hydrofluoric acid may be used as the etchant.

The pattern of the oxide semiconductor layer 140 is formed, and then a heat treatment (OS annealing process) is performed on the oxide semiconductor layer 140 (“OS Annealing Process” in step S1040 of FIG. 6). In the OS annealing process, the oxide semiconductor layer 140 is held at a predetermined reaching temperature for a predetermined time. The predetermined reaching temperature is greater than or equal to 300° C. and less than or equal to 500° C., or greater than or equal to 350° C. and less than or equal to 450° C. The holding time at the reaching temperature is greater than or equal to 15 minutes and less than or equal to 120 minutes, or greater than or equal to 30 minutes and less than or equal to 60 minutes. In the present embodiment, the oxide semiconductor layer 140 is crystallized by the OS annealing process. However, the oxide semiconductor layer 140 does not necessarily have to be crystallized by the OS anneal.

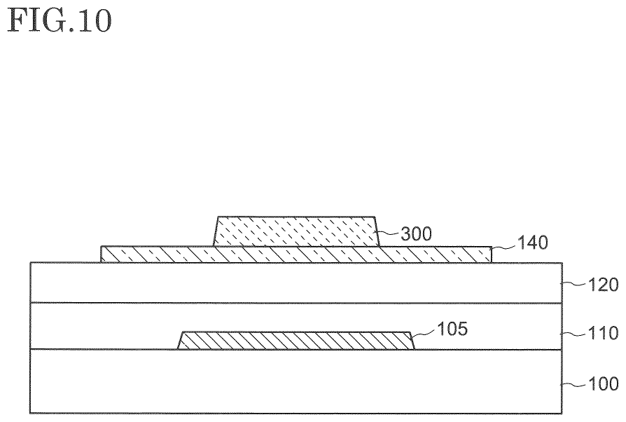

As shown in FIGS. 6 and 10, a mask layer 300 having a predetermined pattern is formed on the oxide semiconductor layer 140 (“Formation of Mask Layer” in step S1050 in FIG. 6). The mask layer 300 may be formed using a resist or a metal. The mask layer 300 is patterned through a photolithography process. The predetermined pattern of the mask layer 300 may substantially match the pattern of the gate electrode 160, or may be different from the pattern of the gate electrode 160. When the predetermined pattern of the mask layer 300 is different from the pattern of the gate electrode 160, the mask layer 300 is formed so that the width of the mask layer 300 substantially matches the width of the gate electrode 160 in a cross-sectional view.

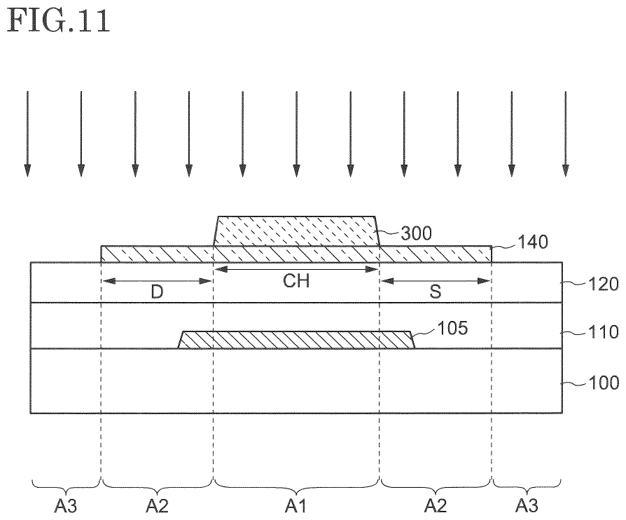

As shown in FIGS. 6 and 11, impurity ions are implanted into the oxide insulating layer 120 using the mask layer 300 as a mask (“First lon Implantation” in step S1060 in FIG. 6). Boron (B), phosphorus (P), argon (Ar), or nitrogen (N) is used as the impurity. As a result, the impurity such as boron (B), phosphorus (P), argon (Ar), nitrogen (N), or the like is introduced into the oxide insulating layer 120. The impurity introduced into the oxide insulating layer 120 forms dangling bond defects DB. The region of the oxide insulating layer 120 where the dangling bond defects DB are formed can function as a hydrogen trapping region.

In the first ion implantation in step S1060, it is important to form dangling bond defects DB in the oxide insulating layer 120 while not forming dangling bond defects DB in the nitride insulating layer 110. Therefore, in the first ion implantation, impurity ions are implanted so as to have a concentration profile with a peak in the oxide insulating layer 120. The position of the peak and the amount of impurity can be controlled by adjusting the ion implantation process parameters (e.g., dose, acceleration voltage, plasma power, etc.). For example, the dose is greater than or equal to 1×10¹⁴/cm², greater than or equal to 5×10¹⁴/cm², or greater than or equal to 1×10¹⁵/cm². For example, the acceleration voltage is greater than 10 keV, greater than or equal to 15 keV, or greater than or equal to 20 keV.

In addition, in step S1060, impurity ions are also introduced into the oxide semiconductor layer 140. Therefore, oxygen deficiencies are formed in the oxide semiconductor layer 140, and the source region S and the drain region D are formed. However, in step S1060, it is not necessary that a sufficient number of oxygen deficiencies are formed in the oxide semiconductor layer 140.

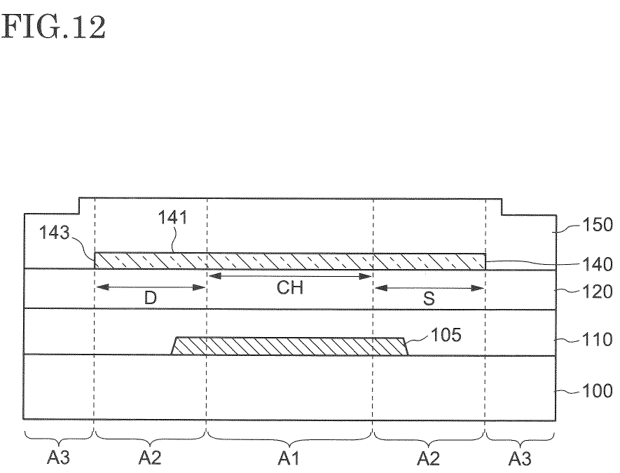

As shown in FIG. 6 and FIG. 12, the gate insulating layer 150 is formed on the oxide semiconductor layer 140 (“GI Formation” in step S1070 of FIG. 6). For example, silicon oxide is formed for the gate insulating layer 150. The gate insulating layer 150 is deposited by a CVD method. For example, the gate insulating layer 150 may be deposited at a deposition temperature greater than or equal to 350° C. in order to form an insulating layer having few defects as described above as the gate insulating layer 150. For example, a thickness of the gate insulating layer 150 is greater than or equal to 100 nm and less than or equal to 500 nm, greater than or equal to 200 nm and less than or equal to 400 nm, or greater than or equal to 250 nm and less than or equal to 350 nm. A process of implanting oxygen may be performed on an upper part of the gate insulating layer 150 after the gate insulating layer 150 is deposited.

A heat treatment (oxidation annealing process) for supplying oxygen to the oxide semiconductor layer 140 is performed in a state where the gate insulating layer 150 is deposited on the oxide semiconductor layer 140 (“Oxidation Annealing Process” in step S1080 of FIG. 6). In the process from the deposition of the oxide semiconductor layer 140 to the deposition of the gate insulating layer 150 on the oxide semiconductor layer 140, a large amount of oxygen deficiencies occurs in the upper surface 141 and the side surface 143 of the oxide semiconductor layer 140. Oxygen released from the oxide insulating layer 120 and the gate insulating layer 150 is supplied to the oxide semiconductor layer 140 by the above-described oxidation annealing process, and the oxygen deficiencies are repaired. When the process of implanting oxygen into the gate insulation layer 150 is not performed, the oxidation annealing process may be performed in a state whereby an insulating layer is capable of releasing oxygen by a heat treatment.

In order to increase the amount of oxygen supplied from the gate insulating layer 150 to the oxide semiconductor layer 140, a metal oxide layer containing aluminum as the main component may be formed on the gate insulating layer 150 by a sputtering method, and then the oxidation annealing process may be performed in that state. When aluminum oxide having a high barrier property is used for the metal oxide layer, it is possible to suppress the oxygen implanted into the gate insulating layer 150 at the time of the oxidation annealing process from being diffused outward. Oxygen implanted into the gate insulating layer 150 is efficiently supplied to the oxide semiconductor layer 140 by forming the metal oxide layer and the oxidation annealing process.

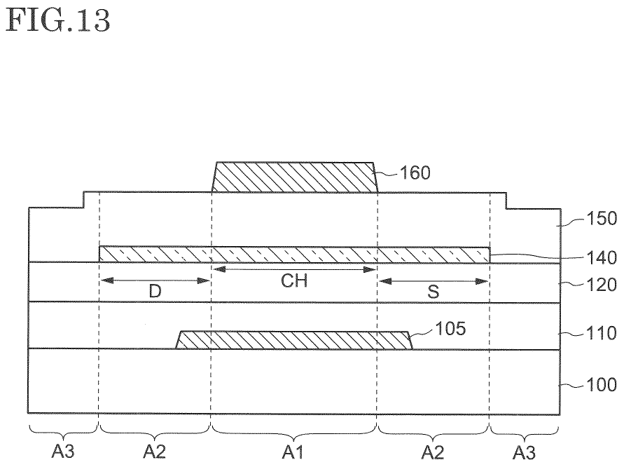

As shown in FIGS. 6 and 13, the gate electrode 160 is deposited and patterned (“GE Formation” in step S1090 of FIG. 6). The gate electrode 160 is deposited by a sputtering method or an atomic layer deposition method. The gate electrode 160 is patterned through a photolithography process.

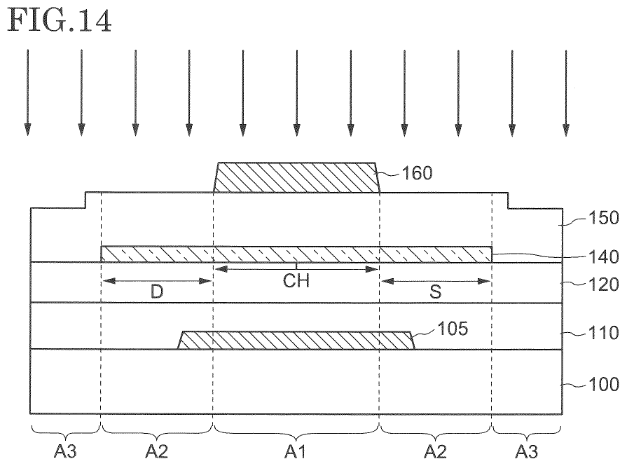

As shown in FIGS. 6 and 14, impurity ions are implanted into the oxide semiconductor layer 140 using the gate electrode 160 as a mask (“Second lon Implantation” in step S1100 in FIG. 6). Boron (B), phosphorus (P), argon (Ar), or nitrogen (N) is used as the impurity. The impurity implanted in the second ion implantation in step S1100 may be the same as or different from the impurity implanted in the first ion implantation in step S1060. As a result, boron (B), phosphorus (P), argon (Ar), nitrogen (N), or the like is introduced into the oxide semiconductor layer 140.

In the second ion implantation in step S1100, the gate electrode 160 is used as a mask. Therefore, the impurity is introduced into the region of the oxide semiconductor layer 140 that does not overlap the gate electrode 160, and oxygen deficiencies are formed. When hydrogen is bonded to the generated oxygen deficiencies, the resistance of the oxide semiconductor layer 140 is reduced. That is, a source region S and a drain region D are formed in the oxide semiconductor layer 140. On the other hand, an impurity is not introduced into the region of the oxide semiconductor layer 140 that overlaps the gate electrode 160, and oxygen deficiencies are not formed. That is, a channel region CH is formed in the oxide semiconductor layer 140. In addition, the impurity is introduced into the gate electrode 160 that is used as a mask.

In the second ion implantation in step S1100, the impurity is also introduced into the gate insulating layer 150 and the oxide insulating layer 120. The impurity introduced into the gate insulating layer 150 and the oxide insulating layer 120 form dangling bond defects DB. Regions of the gate insulating layer 150 and the oxide insulating layer 120 where the dangling bond defects DB are formed can function as hydrogen trapping regions.

The first ion implantation in step S1060 and the second ion implantation in step S1110 form a first region A1, a second region A2, and a third region A3. In the first region A1, the gate electrode 160 contains the impurity. In the second region A2, the oxide insulating layer 120, the oxide semiconductor layer 140, and the gate insulating layer 150 contain the impurity. The oxide semiconductor layer 140 in the second region A2 functions as a source region or a drain region. The oxide insulating layer 120 and the gate insulating layer 150 in the second region A2 function as hydrogen trapping regions. In the third region A3, the oxide insulating layer 120 and the gate insulating layer 150 contain the impurity. The oxide insulating layer 120 and the gate insulating layer 150 in the third region A3 function as hydrogen trapping regions.

In the second ion implantation in step S1100, impurity ions are implanted so as to have a concentration profile with a peak in one of the oxide semiconductor layer 140 and the gate insulating layer 150 in the second region A2. The position of the peak and the amount of impurity can be controlled by adjusting the process parameters of the ion implantation (e.g., dose, acceleration voltage, plasma power, etc.). For example, the dose is greater than or equal to 1×10¹⁴/cm², greater than or equal to 5×10¹⁴/cm², or greater than or equal to 1×10¹⁵/cm². For example, the acceleration voltage is greater than 10 keV, greater than or equal to 15 keV, or greater than or equal to 20 keV.

When hydrogen is introduced in the oxygen deficiencies of the source region S and the drain region D, the resistances of the source region S and the drain region D are reduced. However, if hydrogen enters into the channel region CH, the channel region CH also becomes less resistant, resulting in the appearance of humps or depressions, which deteriorate the electrical characteristics of the semiconductor device 10. Therefore, it is necessary to form a hydrogen trapping region that suppresses hydrogen entry into the channel region CH. In particular, in the formation of the insulating layer 170 described below, it is important to form hydrogen trapping regions not only in the gate insulating layer 150 but also in the oxide insulating layer 120. In the present embodiment, the first ion implantation is performed in step S1060 to form the hydrogen trapping region in the oxide insulating layer 120 before forming the gate insulating layer 150. Therefore, even when the gate insulating layer 150 is thick (e.g., when the gate insulating layer 150 is greater than or equal to 200 nm), impurity ions can be sufficiently implanted into the oxide insulating layer 120 to form dangling bond defects DB and form the hydrogen trapping region.

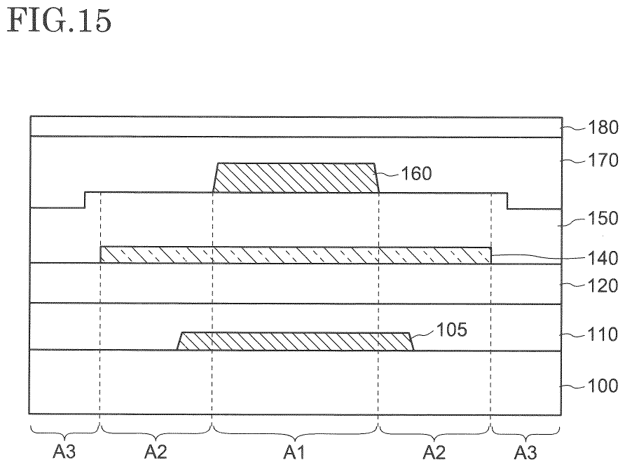

As shown in FIGS. 6 and 15, the insulating layers 170 and 180 are deposited on the gate insulating layer 150 and the gate electrode 160 as interlayer films (“Interlayer Film Deposition” in step S1110 of FIG. 6). The insulating layers 170 and 180 are deposited by a CVD method. For example, a silicon nitride layer is formed as the insulating layer 170, and a silicon oxide layer is formed as the insulating layer 180. The materials used as the insulating layers 170 and 180 are not limited to the above. A thickness of the insulating layer 170 is greater than or equal to 50 nm and less than or equal to 500 nm. A thickness of the insulating layer 180 is greater than or equal to 50 nm and less than or equal to 500 nm.

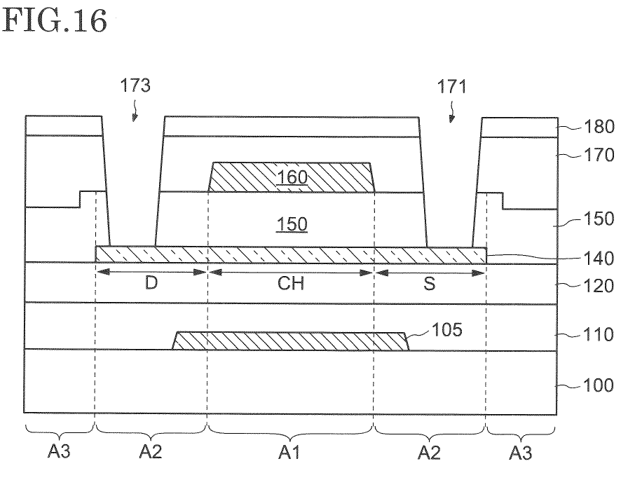

As shown in FIGS. 6 and FIG. 16, the openings 171 and 173 are formed in the insulating layers 170 and 180 (“Opening Contact Hole” in step S1120 of FIG. 6). The source region S is exposed by the opening 171. The drain region D is exposed by the opening 173. The semiconductor device 10 shown in FIG. 1 is completed by forming the source-drain electrode 200 on the exposed source region S and the exposed drain region D by the openings 171 and 173 and on the insulating layer 180 (“SD Formation” in step S1130 of FIG. 6).

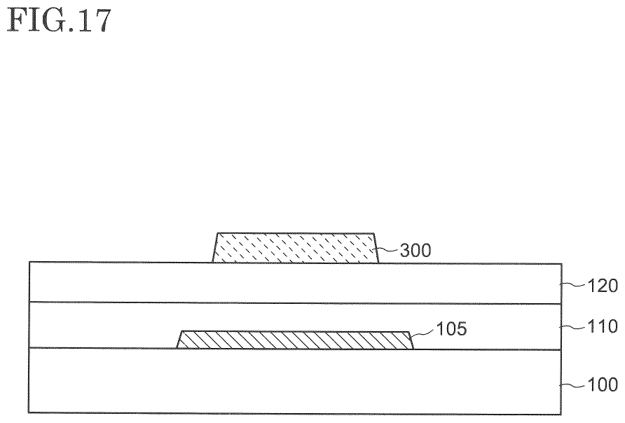

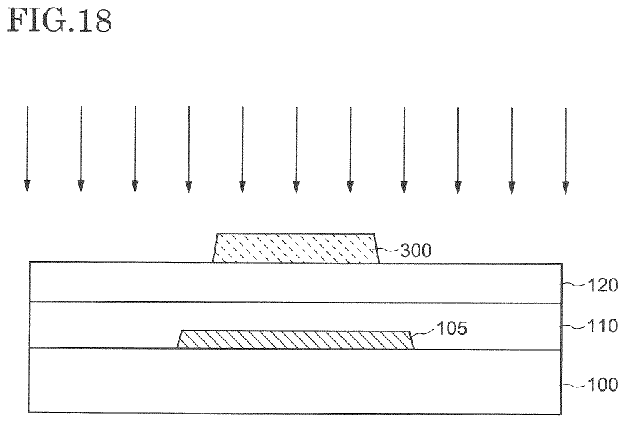

The method for manufacturing the semiconductor device 10 shown in FIG. 1 is not limited to the above-described method. For example, steps S1050 and S1060 may be performed after step S1010. In this case, a mask layer 300 having a predetermined pattern is formed on the oxide insulating layer 120 (see FIG. 17). Further, impurity ions are implanted into the oxide insulating layer 120 using the mask layer 300 as a mask (see FIG. 18). Then, steps S1020 to S1040 and steps S1070 to S1130 are performed in order.

### 5. Hydrogen Trapping in Dangling Bond Defect DB

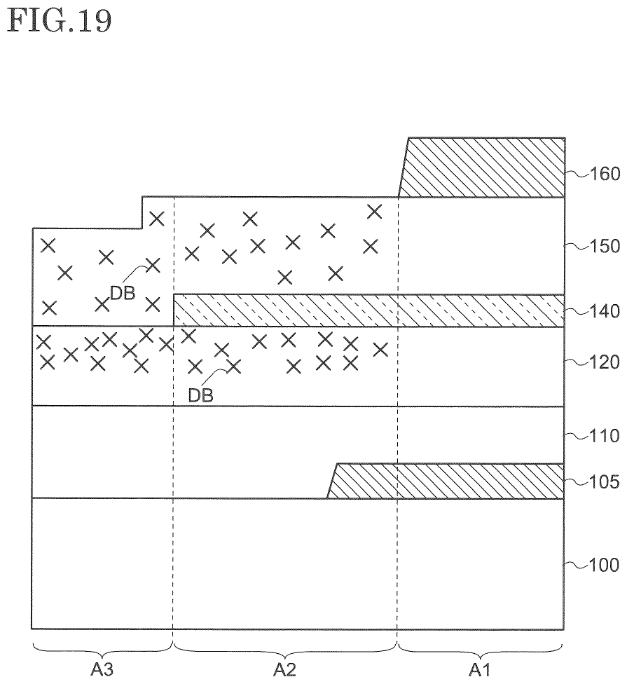

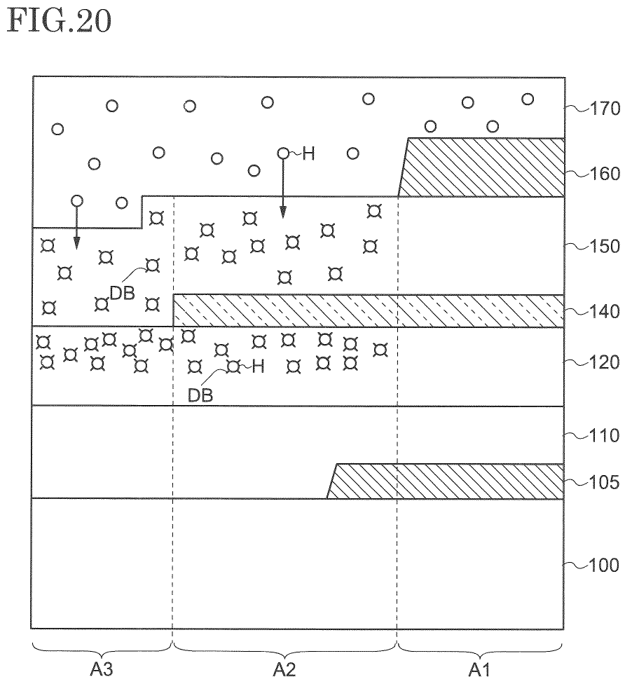

Each of FIGS. 19 and 20 is a schematic cross-sectional view illustrating hydrogen trapping regions in the second region A2 and the third region A3 in the semiconductor device 10 according to an embodiment of the present invention.

As shown in FIG. 19, the impurity is introduced into the oxide insulating layer 120 and the gate insulating layer 150 in the second region A2 and the third region A3, and the dangling bond defects DB are formed in the oxide insulating layer 120 and the gate insulating layer 150 in the second region A2 and the third region A3 by the first ion implantation in step S1060 and the second ion implantation in step S1110.

FIG. 20 shows the state in which the insulating layer 170 is formed. In order for the insulating layer 170 to have a function of blocking impurities diffused from above, the insulating layer 170 is preferably a dense film with few defects. In order to obtain such an insulating layer 170, the insulating layer 170 needs to be deposited at a high temperature. For example, when the silicon nitride layer is formed as the insulating layer 170 at a high temperature, a large amount of hydrogen is contained in the insulating layer 170, so that a large amount of hydrogen is diffused from the insulating layer 170 to the oxide insulating layer 120, the oxide semiconductor layer 140, and the gate insulating layer 150 due to the deposition temperature. Therefore, when the hydrogen trapping regions are not formed in the oxide insulating layer 120 and the gate insulating layer 150, hydrogen diffuses not only into the source region S and the drain region D but also into the channel region CH through the oxide insulating layer 120 and the gate insulating layer 150.

On the other hand, as shown in FIG. 20, when the dangling bond defects DB are formed in the oxide insulating layer 120 and the gate insulating layer 150, hydrogen H diffused from the insulating layer 170 during the formation of the insulating layer 170 is trapped by the dangling bond defects DB (shown as a circle overlaid on an x). That is, regions including the dangling bond defects DB in the oxide insulating layer 120 and the gate insulating layer 150 function as the hydrogen trapping regions. Therefore, in step S1110, hydrogen H diffused from the insulating layer 170 during or after the formation can be prevented from entering the channel region CH. Therefore, since a film containing a large amount of hydrogen can be used as the insulating layer 170, the insulating layer 170 can have a high impurity blocking function. Further, the resistance of the oxide semiconductor layer 140 in the source region S and the drain region D can be sufficiently reduced.

In the present embodiment, the amount of trapped hydrogen H may increase in the order of the oxide insulating layer 120 in the first region A1, the oxide insulating layer 120 in the second region A2, and the oxide insulating layer 120 in the third region A3 based on the distribution of dangling bond defects DB formed in the oxide insulating layer 120.

In the present embodiment, since the hydrogen trapping regions including many dangling bond defects DB are formed in the oxide insulating layer 120 and the gate insulating layer 150 in the second region A2 and the third region A3 surrounding the channel region CH, it is possible to suppress the entry of hydrogen into the channel region CH. As a result, it is possible to obtain a semiconductor device 10 having electrical characteristics in which humps are suppressed.

### Second Embodiment

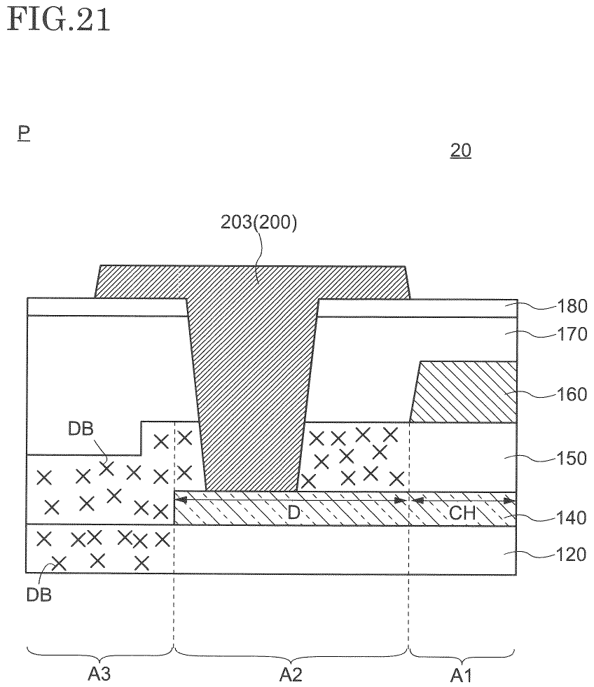

A semiconductor device 20 according to one embodiment of the present invention is described with reference to FIGS. 21 to 26. In addition, when a configuration of the semiconductor device 20 is similar to the configuration of the semiconductor device 10, the description of the semiconductor device 20 may be omitted in the following description.

### 1. Configuration of Semiconductor Device 20 and Materials of Each Member

Since the semiconductor device 20 is generally the same as the semiconductor device 10 shown in FIGS. 1 and 2, the description is omitted here. Further, since the materials of members of the semiconductor device 20 are also the same as those of the semiconductor device 10, the description is omitted here.

### 2. Configuration of Hydrogen Trapping Region

Hydrogen trapping regions are formed in the oxide insulating layer 120 and the gate insulating layer 150. The configuration of the hydrogen trapping regions formed in the oxide insulating layer 120 and the gate insulating layer 150 is described with reference to FIGS. 21, 22A to 22C, and 23A to 23C.

FIG. 21 is a schematic enlarged partial cross-sectional view showing a configuration of a semiconductor device 20 according to an embodiment of the present invention. Specifically, FIG. 21 is an enlarged cross-sectional view of a region P in FIG. 1. Although the region P shown in FIG. 21 is a region in the vicinity of the drain region D, the vicinity of the source region S also has the same configuration as the region P.

Although the gate electrode 160 is used as a mask for the ion implantation of an impurity to form the source region S and the drain region D, the ion implantation of an impurity into the oxide semiconductor layer 140 is performed through the gate insulating layer 150. Therefore, the impurity is also introduced into the gate insulating layer 150 in the second region A2 and the third region A3, thereby forming dangling bond defects DB in the gate insulating layer 150. Further, in the second region A2 and the third region A3, the impurity may pass through the oxide semiconductor layer 140 and the gate insulating layer 150 and be introduced into the oxide insulating layer 120. In addition, the ion implantation of the impurity is performed into the oxide insulating layer 120 separately from the ion implantation of the impurity described above in the present embodiment in order to form dangling bond defects DB in the oxide insulating layer 120 in the third region A3.

As a result, as shown in FIG. 21, dangling bond defects DB are formed in the gate insulating layer 150 in the second region A2 and dangling bond defects DB are formed in the oxide insulating layer 120 and the gate insulating layer 150 in the third region A3. When silicon oxide is used for each of the oxide insulating layer 120 and the gate insulating layer 150, silicon dangling bond defects DB are formed in the oxide insulating layer 120 and the gate insulating layer 150.

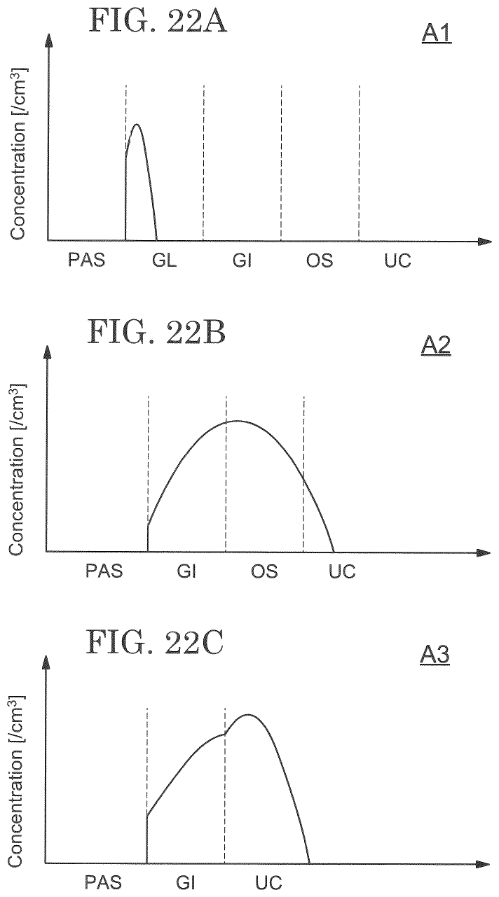

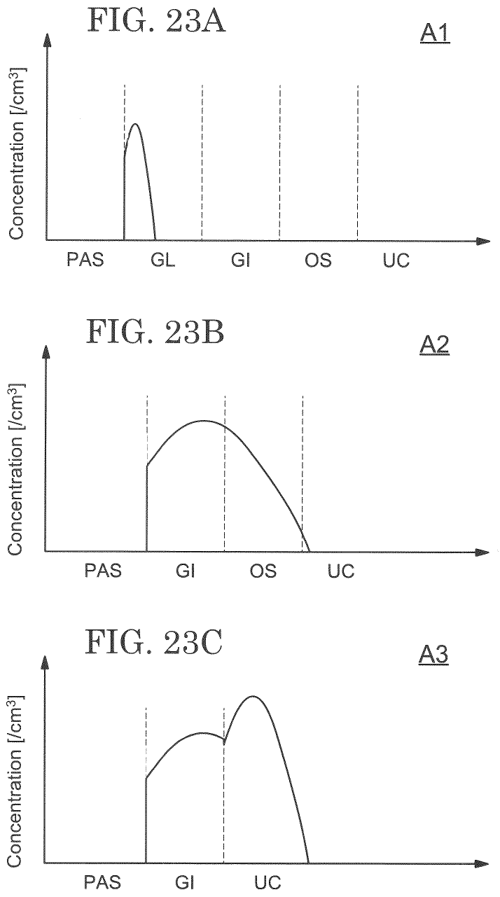

Each of FIGS. 22A to 22C and 23A to 23C is a graph showing concentration profiles of the impurity in the first region A1 to the third region A3 in a semiconductor device according to an embodiment of the present invention. Specifically, each of FIGS. 22A and 23A shows a concentration profile of the impurity in the first region A1, each of FIGS. 22B and 23B shows a concentration profile of the impurity in the second region A2, and each of FIGS. 22C and 23C shows a concentration profile of the impurity in the third region A3. In each of the graphs of FIGS. 22A to 22C and 23A to 23C, the vertical axis indicates the concentration of the impurity per unit volume (Concentration [/cm³]), and the horizontal axis indicates the name of the layer in the stacking direction (Film thickness direction). On the horizontal axis, “UC” corresponds to the oxide insulating layer 120 and the nitride insulating layer 110. “OS” corresponds to the oxide semiconductor layer 140. “GI” corresponds to the gate insulating layer 150. “GL” corresponds to the gate electrode 160. “PAS” corresponds to the insulating layer 170.

As shown in FIGS. 22A and 23A, the concentration profile of the impurity has peaks in the gate electrode 160 (GL) in the first region A1. That is, the first region A1 includes two peaks. Metal materials have a high blocking property for the impurity introduced by ion implantation. When a metal material is used for the gate electrode 160, the impurity is blocked by the gate electrode 160 and does not reach the gate insulating layer 150 (GI). Therefore, dangling bond defects DB due to the introduction of the impurity are not formed in the gate insulating layer 150 in the first region A1. However, the impurity may reach the gate insulating layer 150 as long as it does not affect the electrical characteristics of the semiconductor device 20.

As shown in FIG. 22B, the concentration profile of the impurity has peaks in the oxide semiconductor layer 140 (OS) in the second region A2. That is, the second region A2 includes one peak. In the stacking direction in the second region A2, the concentration of the impurity at the peak position of the oxide semiconductor layer 140 is greater than the concentration of the impurity in the gate insulating layer 150. The purpose of introducing the impurity into the second region A2 is to form the source region S and the drain region D. Therefore, although it is preferable to set the ion implantation conditions so as to obtain the above-described concentration profile, the concentration profile of the impurity is not limited thereto. The concentration profile of the impurity in the second region A2 may have a peak in the gate insulating layer 150 (GI) (see FIG. 23B). In this case, in the stacking direction in the second region A2, the concentration of the impurity at the peak position of the gate insulating layer 150 is greater than the concentration of the impurity in the oxide semiconductor layer 140.

As shown in FIG. 22C, the concentration profile of the impurity has a peak in the oxide insulating layer 120 (UC) in the third region A3. That is, the third region A3 includes one peak. In the stacking direction in the third region A3, the concentration of the impurity at the peak position of the oxide insulating layer 120 is greater than the concentration of the impurity contained in the gate insulating layer 150. The concentration profile of the impurity of the gate insulating layer 150 in the third region A3 is substantially the same as the concentration profile of the impurity of the gate insulating layer 150 in the second region A2. Therefore, the concentration profile of the impurity in the third region A3 shown in FIG. 23C may have peaks in the oxide insulating layer 120 (UC) and the gate insulating layer 150 (GI). In this case, the third region A3 includes two peaks.

Although details are described later, at least two ion implantations of an impurity are performed in the present embodiment. In the first ion implantation of the impurity, the impurity ions are introduced into the oxide insulating layer 120 in the third region A3. On the other hand, in the second ion implantation of the impurity, the impurity ions are introduced into the oxide insulating layer 120 in the second region A2 and the third region A3 through the gate insulating layer 150. In addition, the impurity may be introduced into the oxide insulating layer 120 in the second ion implantation. Therefore, in the oxide insulating layer 120 in the first region A1, the second region A2, and the third region A3, the concentrations of the impurity may increase in the order of the first region A1, the second region A2, and the third region A3. In addition, when the impurity is introduced into the oxide insulating layer 120 in the second region A2, the concentration of the impurity in the oxide insulating layer 120 in the second region A2 is less than 1×10¹⁶/cm³.

In the present embodiment, the concentration of the impurity contained at a predetermined position in the oxide insulating layer 120 in the stacking direction in the third region A3 is greater than or equal to 1×10¹⁶/cm³, greater than or equal to 1×10¹⁷/cm³, or greater than or equal to 1×10¹⁸/cm³. The predetermined position may be the peak position of the concentration profile, or may be a position corresponding to the interface between the oxide insulating layer 120 and the gate insulating layer 150. Alternatively, the predetermined position may be a position shifted by a predetermined depth toward the oxide insulating layer 120 from the position corresponding to the interface.

With reference to FIG. 2, the channel region CH corresponds to the first region A1, the source region S and the drain region D correspond to the second region A2, and the regions other than the channel region CH, the source region S, and the drain region D correspond to the third region A3. That is, the channel region CH is sandwiched by the second regions A2, and is surrounded by the third regions A3. Therefore, hydrogen diffused from the insulating layer 170 during the formation of the insulating layer 170 is trapped by hydrogen trapping regions formed in the gate insulating layer 150 in the second region A2 and the third region A3 located around the channel region CH, and the oxide insulating layer 120 in the third region A3. As a result, it is possible to suppress the entry of the hydrogen into the channel region CH.

### 3. Method for Manufacturing Semiconductor Device 20

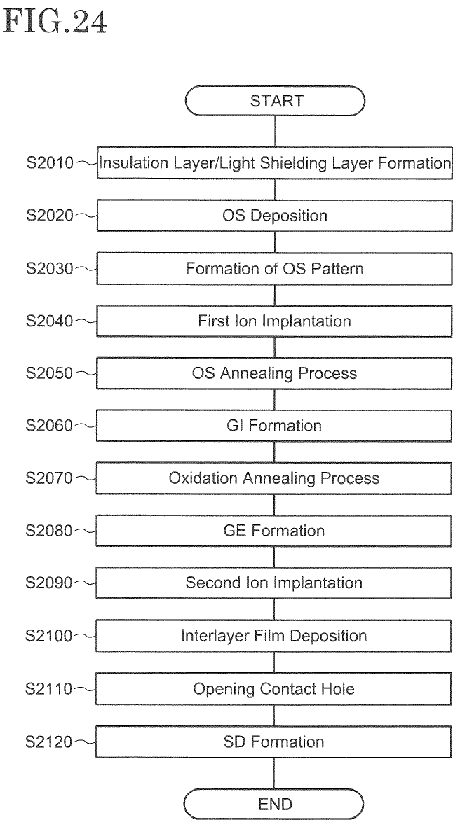

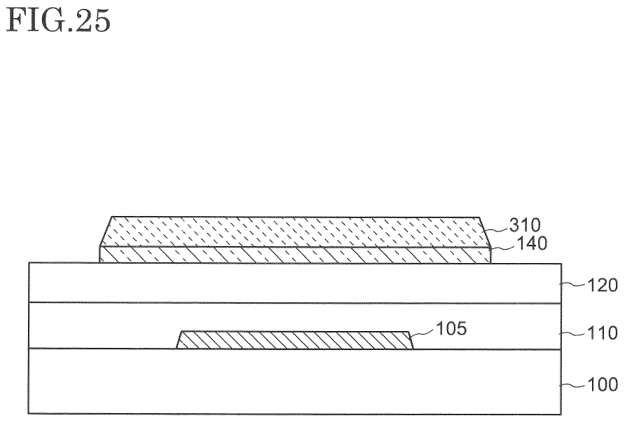

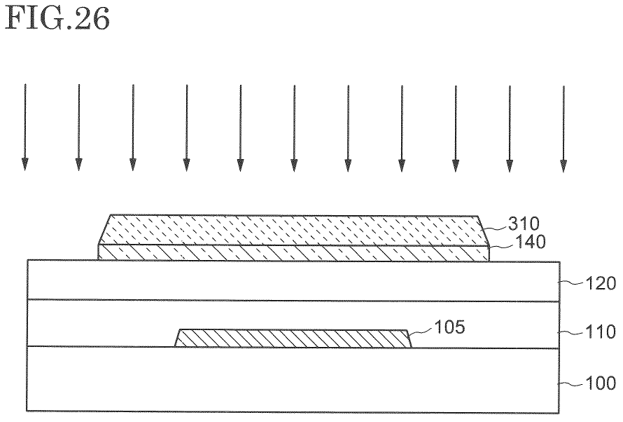

A method for manufacturing the semiconductor device 20 according to an embodiment of the present invention is described with reference to FIGS. 24 to 26. FIG. 24 is a sequence diagram showing a method for manufacturing the semiconductor device 20 according to an embodiment of the present invention. FIGS. 25 and 26 are cross-sectional views showing a method for manufacturing the semiconductor device 20 according to an embodiment of the present invention.

Steps S2010 to S2030 shown in FIG. 24 are similar to steps S1010 to S1030 shown in FIG. 6. However, in step S2030, a resist mask 310 used for patterning the oxide semiconductor layer 140 is not removed but remains, as shown in FIG. 25.

As shown in FIGS. 24 and 26, impurity ions are implanted into the oxide insulating layer 120 using the resist mask 310 as a mask (“First Ion Implantation” in step S2040 in FIG. 24). Boron (B), phosphorus (P), argon (Ar), or nitrogen (N) is used as the impurity. As a result, the impurity such as boron (B), phosphorus (P), argon (Ar), nitrogen (N), or the like is introduced into the oxide insulating layer 120. The impurity introduced into the oxide insulating layer 120 forms dangling bond defects DB. The region of the oxide insulating layer 120 where the dangling bond defects DB are formed can function as a hydrogen trapping region.

In the first ion implantation in step S1060, it is important to form dangling bond defects DB in the oxide insulating layer 120 while not forming dangling bond defects DB in the nitride insulating layer 110. Therefore, in the first ion implantation, impurity ions are implanted so as to have a concentration profile with a peak in the oxide insulating layer 120. The position of the peak and the amount of impurity can be controlled by adjusting the ion implantation process parameters (e.g., dose, acceleration voltage, plasma power, etc.). For example, the dose is greater than or equal to 1×10¹⁴/cm², greater than or equal to 5×10¹⁴/cm², or greater than or equal to 1×10¹⁵/cm². For example, the acceleration voltage is greater than 10 keV, greater than or equal to 15 keV, or greater than or equal to 20 keV.

In addition, the resist mask 310 is removed after the impurity is added to the oxide insulating layer 120.

After the first ion implantation in step S2040, a heat treatment (OS annealing process) is performed on the oxide semiconductor layer 140 (“OS Annealing Process” in step S2050 in FIG. 24). Step S2040 is similar to step S1050.

Steps S2060 to S2120 shown in FIG. 24 are similar to steps S1070 to S1130 shown in FIG. 6.

In the present embodiment, the amount of trapped hydrogen H may increase in the order of the oxide insulating layer 120 in the first region A1, the oxide insulating layer 120 in the second region A2, and the oxide insulating layer 120 in the third region A3, based on the distribution of dangling bond defects DB formed in the oxide insulating layer 120.

In the present embodiment, since the hydrogen trapping regions including many dangling bond defects DB are formed in the oxide insulating layer 120 and the gate insulating layer 150 in the second region A2 and the third region A3 surrounding the channel region CH, it is possible to suppress the entry of hydrogen into the channel region CH. As a result, it is possible to obtain a semiconductor device 20 having electrical characteristics in which humps are suppressed.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device, comprising:
an oxide insulating layer;
an oxide semiconductor layer over the oxide insulating layer;
a gate insulating layer over the oxide semiconductor layer; and
a gate electrode over the gate insulating layer,
wherein in a first region in which the oxide insulating layer, the oxide semiconductor layer, the gate insulating layer, and the gate electrode are stacked in this order, the gate electrode contains an impurity,
wherein in a second region in which the gate electrode is not included and the oxide insulating layer, the oxide semiconductor layer, and the gate insulating layer are stacked in this order, the oxide insulating layer, the oxide semiconductor layer, and the gate insulating layer contain the impurity,
wherein in a third region in which the gate electrode and the oxide semiconductor layer are not included and the oxide insulating layer and the gate insulating layer are stacked in this order, the oxide insulating layer and the gate insulating layer contain the impurity, and
wherein in a stacked direction of the second region, a concentration profile of the impurity comprises a first peak and a second peak.

2. The semiconductor device according to claim 1, wherein the first peak is included in the oxide insulating layer.

3. The semiconductor device according to claim 2, wherein the second peak is included in the oxide semiconductor layer.

4. The semiconductor device according to claim 2, wherein the second peak is included in the gate insulating layer.

5. The semiconductor device according to claim 1, wherein in a stacked direction of the third region, a concentration profile of the impurity comprises a third peak and a fourth peak.

6. The semiconductor device according to claim 5, wherein the third peak is included in the oxide insulating layer.

7. The semiconductor device according to claim 6, wherein the fourth peak is included in the gate insulating layer.

8. A semiconductor device, comprising:
an oxide insulating layer;
an oxide semiconductor layer over the oxide insulating layer;
a gate insulating layer over the oxide semiconductor layer; and
a gate electrode over the gate insulating layer,
wherein in a first region in which the oxide insulating layer, the oxide semiconductor layer, the gate insulating layer, and the gate electrode are stacked in this order, the gate electrode contains an impurity,
wherein in a second region in which the gate electrode is not included and the oxide insulating layer, the oxide semiconductor layer, and the gate insulating layer are stacked in this order, the oxide semiconductor layer and the gate insulating layer contain the impurity,
wherein in a third region in which the gate electrode and the oxide semiconductor layer are not included and the oxide insulating layer and the gate insulating layer are stacked in this order, the oxide insulating layer and the gate insulating layer contain the impurity, and
wherein in a stacked direction of the third region, a concentration profile of the impurity comprises a first peak and a second peak.

9. The semiconductor device according to claim 8, wherein the first peak is included in the oxide insulating layer.

10. The semiconductor device according to claim 9, wherein the second peak is included in the gate insulating layer.

11. The semiconductor device according to claim 8, wherein in the second region, a concentration of the impurity included in the oxide insulating layer is less than 1×10¹⁶/cm³.

12. The semiconductor device according to claim 1, wherein the impurity is one selected from the group consisting of boron, phosphorus, argon, and nitrogen.

13. The semiconductor device according to claim 1, wherein a thickness of the gate insulating layer is greater than or equal to 100 nm.

14. A method for manufacturing a semiconductor device, comprising the steps of:
forming an oxide insulating layer;
forming a mask layer having a first pattern over the oxide insulating layer;
implanting a first impurity into the oxide insulating layer using the mask layer as a mask;
forming an oxide semiconductor layer having a second pattern over the oxide insulating layer;
forming a gate insulating layer over the oxide insulating layer and the oxide semiconductor layer so as to cover the oxide semiconductor layer;
forming a gate electrode having a third pattern over the gate insulating layer; and
implanting a second impurity into the oxide semiconductor layer using the gate electrode as a mask.

15. The method for manufacturing a semiconductor device according to claim 14, wherein the first pattern and the third pattern substantially coincide with each other.

16. The method for manufacturing a semiconductor device according to claim 14, wherein the first impurity and the second impurity are a same element.

17. The method for manufacturing a semiconductor device according to claim 14, wherein the first impurity and the second impurity are different elements from each other.

18. The method for manufacturing a semiconductor device according to claim 14, wherein each of the first impurity and the second impurity is one selected from the group consisting of boron, phosphorus, argon, and nitrogen.

19. The method for manufacturing a semiconductor device according to claim 14, wherein a thickness of the gate insulating layer is greater than or equal to 100 nm.
